(19) United States
(12) Patent Application Publication
(10) Pub. No.: US 2025/0140720 A1
(43) Pub. Date: May 1, 2025

(54) SEMICONDUCTOR PACKAGE

(71) Applicant: SAMSUNG ELECTRONICS CO., LTD., Suwon-si (KR)

(72) Inventor: DAWOON JUNG, Suwon-si (KR)

(73) Assignee: SAMSUNG ELECTRONICS CO., LTD., Suwon-si (KR)

(21) Appl. No.: 18/763,547

(22) Filed: Jul. 3, 2024

(30) Foreign Application Priority Data
Oct. 30, 2023 (KR) 10-2023-0147205

(51) Int. Cl. H01L 23/00; H01L 23/31; H01L 23/48; H01L 25/065

(52) U.S. Cl. CPC H01L 24/05; H01L 23/3157; H01L 24/08; H01L 25/0657; H01L 23/3107; H01L 23/481; H01L 24/16; H01L 2224/02206; H01L 2224/05147; H01L 2224/05611; H01L 2224/05639; H01L 2224/05644; H01L 2224/05655; H01L 2224/08146; H01L 2224/08503; H01L 2224/16221

(57) ABSTRACT

A semiconductor package includes a first semiconductor chip, a chip structure on the first semiconductor chip, and a bonding structure between the first semiconductor chip and the chip structure, where the bonding structure includes a first conductive pad on an upper surface of the first semiconductor chip, a second conductive pad on a lower surface of the chip structure, a protective metal layer between the first conductive pad and the second conductive pad, and an intermetallic compound in the protective metal layer, where the protective metal layer covers a surface of the first conductive pad and a surface of the second conductive pad, where the semiconductor package further includes a first interface between the first semiconductor chip and the chip structure and a second interface between the protective metal layer and the second conductive pad.

### CROSS-REFERENCE TO RELATED APPLICATIONS

This application is based on and claims priority to Korean Patent Application No. 10-2023-0147205, filed on Oct. 30, 2023, in the Korean Intellectual Property Office, the disclosure of which is incorporated by reference herein in its entirety.

### BACKGROUND

Example embodiments of the disclosure relate to a semiconductor package, and more particularly to a semiconductor package including a protective metal layer on a conductive pad.

A semiconductor package may be provided to implement an integrated circuit chip for use in electronic products. Typically, the semiconductor package includes a semiconductor chip mounted on a printed circuit board (PCB) and bonding wirings or bumps may be used to electrically connect the semiconductor chip to the printed circuit board. With the development of electronic industry, various studies have been conducted to improve reliability and durability of semiconductor packages.

Information disclosed in this Background section has already been known to or derived by the inventors before or during the process of achieving the embodiments of the present application, or is technical information acquired in the process of achieving the embodiments. Therefore, it may contain information that does not form the prior art that is already known to the public.

### SUMMARY

One or more example embodiments of the disclosure provide a semiconductor package with improved durability and reliability.

Additional aspects will be set forth in part in the description which follows and, in part, will be apparent from the description, or may be learned by practice of the presented embodiments.

According to an aspect of an example embodiment, a semiconductor package may include a first semiconductor chip, a chip structure on the first semiconductor chip, and a bonding structure between the first semiconductor chip and the chip structure, where the bonding structure includes a first conductive pad on an upper surface of the first semiconductor chip, a second conductive pad on a lower surface of the chip structure, a protective metal layer between the first conductive pad and the second conductive pad, and an intermetallic compound in the protective metal layer, where the protective metal layer covers a surface of the first conductive pad and a surface of the second conductive pad, where the upper surface of the first semiconductor chip and the lower surface of the chip structure directly contact each other, where the semiconductor package further includes a first interface between the first semiconductor chip and the chip structure and a second interface between the protective metal layer and the second conductive pad, and where a first level of the first interface is equal to or lower than a second level of the second interface.

According to an aspect of an example embodiment, a semiconductor package may include a first semiconductor chip including a first upper conductive pad on an upper surface of the first semiconductor chip, a first lower conductive pad on a lower surface of the first semiconductor chip, and a first through via connected to the first upper conductive pad and the first lower conductive pad, second semiconductor chip, a third semiconductor chip, a fourth semiconductor chip, and a fifth semiconductor chip sequentially stacked on the first semiconductor chip, where the second semiconductor chip includes a second upper conductive pad on an upper surface of the second semiconductor chip, and a second lower conductive pad on a lower surface of the second semiconductor chip, and a first bonding structure between the first semiconductor chip and the second semiconductor chip, where the first bonding structure includes the first upper conductive pad, the second lower conductive pad, a protective metal layer between the first upper conductive pad and the second lower conductive pad, an intermetallic compound in the protective metal layer, and a diffusion barrier surrounding the first upper conductive pad and the second lower conductive pad, where the protective metal layer covers a surface of the first upper conductive pad and a surface of the second lower conductive pad, wherein the upper surface of the first semiconductor chip and the lower surface of the second semiconductor chip directly contact each other, where the semiconductor package further includes a first interface between the first semiconductor chip and the second semiconductor chip and a second interface between the protective metal layer and the second lower conductive pad, and where a first level of the first interface is equal to or lower than a second level of the second interface.

According to an aspect of an example embodiment, a semiconductor package may include a package substrate, an interposer substrate on the package substrate, at least one semiconductor chip structure on the interposer substrate, internal connection members connecting the interposer substrate and the at least one semiconductor chip structure, and a mold layer at least partially covering the interposer substrate and the at least one semiconductor chip structure, where the at least one semiconductor chip structure includes a first semiconductor chip, second semiconductor chips on the first semiconductor chip, the second semiconductor chips including a lowermost second semiconductor chip, and a bonding structure between the first semiconductor chip and the lowermost second semiconductor chip, where the bonding structure includes a first conductive pad on an upper surface of the first semiconductor chip, a second conductive pad on a lower surface of the lowermost second semiconductor chip, a protective metal layer between the first conductive pad and the second conductive pad, and an intermetallic compound in the protective metal layer, where the protective metal layer covers a surface of the first conductive pad and a surface of the second conductive pad, where the upper surface of the first semiconductor chip and the lower surface of the chip structure directly contact each other, where the at least one semiconductor chip structure includes a first interface between the first semiconductor chip and the second conductive pad and a second interface between the protective metal layer and the second conductive pad, and where a first level of the first interface is equal to or lower than a second level of the second interface.

### BRIEF DESCRIPTION OF DRAWINGS

The above and other aspects, features, and advantages of certain example embodiments of the present disclosure will be more apparent from the following description taken in conjunction with the accompanying drawings, in which:

FIG. 1 is a cross-sectional view of a semiconductor package according to one or more embodiments of the disclosure;

FIG. 2 is an enlarged view of portion ‘P1’ portion of FIG. 1 according to one or more embodiments of the disclosure;

FIG. 3 is an enlarged view of portion ‘P2’ of FIG. 2 according to one or more embodiments of the disclosure;

FIGS. 4A to 4G are enlarged views of additional examples corresponding to portion ‘P1’ of FIG. 1 according to one or more embodiments of the disclosure;

FIGS. 5A to 5L are cross-sectional views of a process for manufacturing the semiconductor package according to one or more embodiments of the disclosure;

FIG. 6 is a diagram of a process of manufacturing the semiconductor package according to one or more embodiments of the disclosure; and

FIG. 7 is a cross-sectional view of a semiconductor package according to one or more embodiments of the disclosure.

### DETAILED DESCRIPTION

Hereinafter, example embodiments of the disclosure will be described in detail with reference to the accompanying drawings. The same reference numerals are used for the same components in the drawings, and redundant descriptions thereof will be omitted. The embodiments described herein are example embodiments, and thus, the disclosure is not limited thereto and may be realized in various other forms.

As used herein, expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

Various components are described herein as covering or surrounding other components. It will be understood that “cover” or “surround” may indicate a full covering or surrounding, or a partial covering or surrounding, unless the context or terminology dictates otherwise.

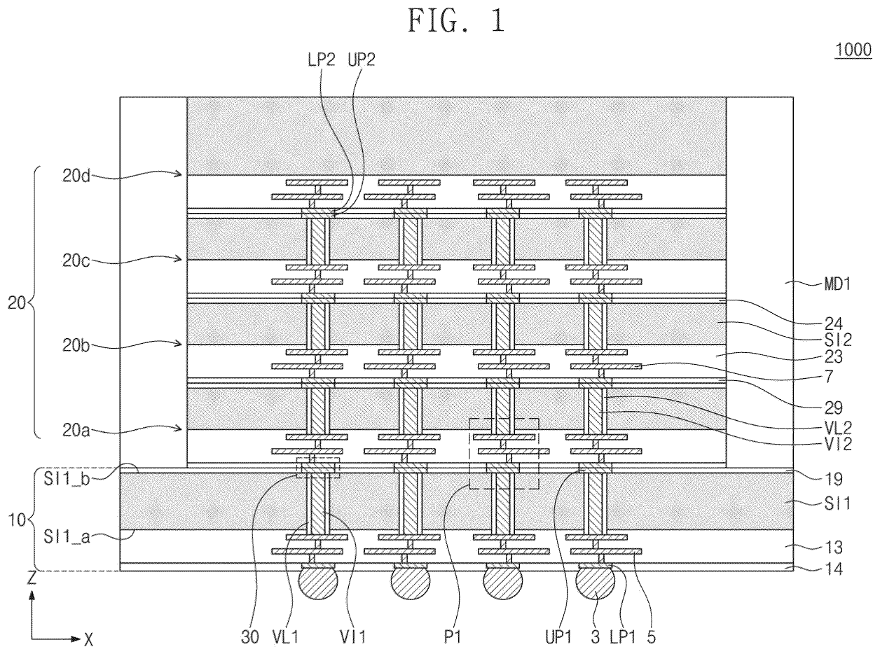

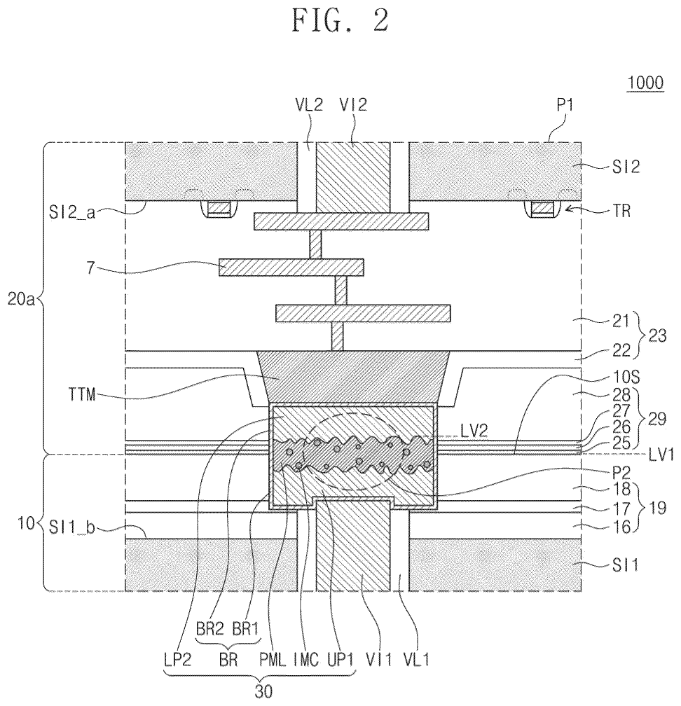

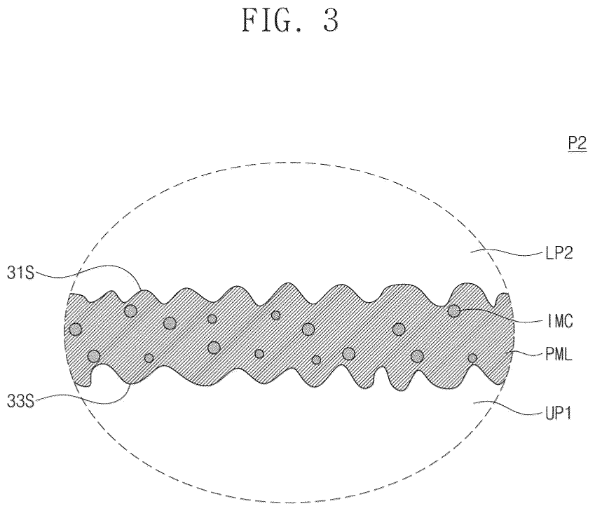

FIG. 1 is a cross-sectional view of a semiconductor package according to one or more embodiments of the disclosure. FIG. 2 is an enlarged view of portion ‘P1’ portion of FIG. 1 according to one or more embodiments of the disclosure. FIG. 3 is an enlarged view of portion ‘P2’ of FIG. 2 according to one or more embodiments of the disclosure.

Referring to FIGS. 1 and 2, a semiconductor package 1000 according to some embodiments may include a first semiconductor chip 10, a chip structure 20, and a first mold layer MD1. The semiconductor package 1000 may further include a bonding structure 30 formed between the first semiconductor chip 10 and the chip structure 20.

The first semiconductor chip 10 may be, for example, a logic circuit chip or a memory chip such as a flash memory chip, dynamic random access memory (RAM) (DRAM) chip, static RAM (SRAM) chip, electrically erasable programming read-only memory (ROM) (EEPROM) chip, phase-change RAM (PRAM) chip, magnetoresistive RAM (MRAM) chip, resistive RAM (ReRAM) chip, etc. The chip structure 20 may include second to fifth semiconductor chips 20a, 20b, 20c, and 20d sequentially stacked. The second to fifth semiconductor chips 20a, 20b, 20c, and 20d may be different chips from the first semiconductor chip 10. The second to fifth semiconductor chips 20a, 20b, 20c, and 20d may be the same memory chip. The memory chip may be, for example, DRAM, NAND Flash, SRAM, MRAM, PRAM, or RRAM.

In some embodiments, a structure in which one logic circuit chip and four memory chips are stacked is provided, but the number of stacked logic circuit chips and memory chips is not limited thereto and may be variously changed. For example, eight or more memory chips may be stacked. The semiconductor package 1000 may have a high bandwidth memory (HBM) chip structure. Alternatively, the semiconductor package 1000 may be a semiconductor package having a bonding structure such as die to die bonding, die to wafer bonding, or wafer on wafer bonding.

Referring to FIGS. 1 and 2, the first semiconductor chip 10 may include a first substrate SI1 and a first interlayer insulating layer 13. The first substrate SI1 may be a semiconductor substrate formed of a semiconductor such as silicon, a silicon on insulator (SOI) substrate, and/or an insulating substrate. The first substrate SI1 may include a front surface SI1_a and a rear surface SI1_b that are opposite to each other. A plurality of transistors may be disposed on the front surface SI1_a of the first substrate SI1. The first interlayer insulating layer 13 may cover the front surface SI1_a of the first substrate SI1 and the transistors. The first interlayer insulating layer 13 may have a single-layer or multi-layer structure of at least one of silicon oxide, silicon nitride, and silicon oxynitride. Multi-layer first internal wirings 5 may be disposed in the first interlayer insulating layer 13. The first internal wirings 5 may be formed of metal such as aluminum, tungsten, titanium, or copper. The first internal wirings 5 and the transistors may form various circuits.

The first semiconductor chip 10 may include a first through via VI1. The first through via VI1 may penetrate the first substrate SI1 and a portion of the first interlayer insulating layer 13. The first internal wirings 5 may be connected to the first through via VI1. A first through insulating layer VL1 may be interposed between the first through via VI1 and the first substrate SI1. The first through via VI1 may include metal such as copper, aluminum, or tungsten. The first through insulating layer VL1 may have a single-layer or multi-layer structure of at least one of silicon oxide, silicon nitride, and silicon oxynitride. The first through insulating layer VL1 may include an air gap.

First upper conductive pads UP1 may be disposed on an upper surface of the first semiconductor chip 10. The first upper conductive pads UP1 may each be connected to the first through via VI1. First lower conductive pads LP1 may be disposed on a lower surface of the first semiconductor chip 10. The first lower conductive pads LP1 may be connected to the first upper conductive pads through the first through via VI1. For example, the first upper conductive pads UP1 and the first lower conductive pads LP1 may each include copper. However, the disclosure is not limited thereto, the first upper conductive pads UP1 and the first lower conductive pads LP1 may each include a metal such as gold, nickel, aluminum, or tungsten. External connection members 3 may each be bonded to the first lower conductive pads LP1. The external connection members 3 may include at least one of a conductive bump and a solder ball. The external connection members 3 may include at least one metal of copper, nickel, tin, and silver.

A first upper passivation layer 19 may cover the first upper conductive pads UP1 and the rear surface SI1_b of the first substrate SI1. As shown in FIG. 2, the first upper passivation layer 19 may include second to fourth upper passivation layers 16, 17, and 18 sequentially stacked. The second upper passivation layer 16 may cover the rear surface SI1_b and the first through insulating layer VL1 of the first substrate SI1. The first lower passivation layer 14 may cover the first lower conductive pads LP1 and the front surface SI1_a of the first substrate SI1. The passivation layers 16 to 19 may each have a single-layer or multi-layer structure of at least one of silicon oxide, silicon nitride, and silicon carbonitride.

The second to fifth semiconductor chips 20a, 20b, 20c, and 20d may each include a second substrate SI2 and a second interlayer insulating layer 23. The bonding structure 30 may be provided. A plurality of bonding structures 30 may be interposed between the second to fifth semiconductor chips 20a, 20b, 20c, and 20d.

The second substrate SI2 may be a semiconductor substrate formed of a semiconductor such as silicon, a SOI substrate, and/or an insulating substrate. The second substrate SI2 may include a front surface SI2_a and a rear surface SI2_b that are opposite to each other. A plurality of transistors TR may be disposed on the front surface SI2_a of the second substrate SI2. The second interlayer insulating layer 23 may cover the front surface SI2_a of the second substrate SI2 and the transistors TR. Referring to FIG. 2, the second interlayer insulating layer 23 may include third and fourth interlayer insulating layers 21 and 22 that are sequentially stacked. An auxiliary pattern TTM may be disposed on the third interlayer insulating layer 21. The auxiliary pattern TTM may include aluminum, for example. The fourth interlayer insulating layer 22 may cover the third interlayer insulating layer 21 and the auxiliary pattern TTM. The second to fourth interlayer insulating layers 21, 22, and 23 may have a single-layer or multi-layer structure of at least one of silicon oxide, silicon nitride, and silicon oxynitride. Multi-layered second internal wirings 7 may be disposed in the second interlayer insulating layer 23. The second internal wirings 7 may be formed of metal such as aluminum, tungsten, titanium, or copper. The second internal wirings 7 and the transistors TR may form various circuits.

The second to fifth semiconductor chips 20a, 20b, 20c, and 20d may each include a second through via VI2. However, the fifth semiconductor chip 20d may not include the second through via VI2. The second through via VI2 may penetrate the second substrate SI2 and a portion of the second interlayer insulating layer 23. The second internal wirings 7 may be connected to the second through via VI2. A second through insulating layer VL2 may be interposed between the second through via VI2 and the second substrate SI2. The second through via VI2 may include metal such as copper, aluminum, or tungsten. The second through insulating layer VL2 may have a single-layer or multi-layer structure of at least one of silicon oxide, silicon nitride, and silicon oxynitride. The second through insulating layer VL2 may include an air gap.

Second upper conductive pads UP2 may be disposed on upper surfaces of the second to fifth semiconductor chips 20a, 20b, 20c, and 20d, respectively. The fifth semiconductor chip 20d may not include the second upper conductive pad UP2. The second upper conductive pads UP2 may each be connected to the second through via VI2. Second lower conductive pads LP2 may be disposed on lower surfaces of the second to fifth semiconductor chips 20a, 20b, 20c, and 20d. The second lower conductive pads LP2 may be connected to the second upper conductive pads through the second through via VI2. For example, the second upper conductive pads UP2 and the second lower conductive pads LP2 may each include copper. However, the disclosure is not limited thereto, the second upper conductive pads UP2 and the second lower conductive pads LP2 may each include a metal such as gold, nickel, aluminum, or tungsten.

The first upper conductive pads UP1 of the first semiconductor chip 10 may be bonded to the second lower conductive pads LP2 of the second semiconductor chip 20a. The first upper conductive pads UP1 and the second lower conductive pads LP2 bonded to each other may form the bonding structures 30.

Adjacent second upper conductive pads UP2 and second lower conductive pads LP2 may be bonded to each other. For example, the second upper conductive pads UP2 of the second semiconductor chip 20a may be bonded to the second lower conductive pads LP2 of the third semiconductor chip 20b. The second upper conductive pads UP2 and the second lower conductive pads LP2 bonded to each other may form the bonding structures 30.

A fifth upper passivation layer 24 may cover the second upper conductive pads UP2, the second through insulating layer VL2, and the rear surface SI2_b of the second substrate SI2. A second lower passivation layer 29 may cover lower surfaces of the second lower conductive pads LP2 and the second interlayer insulating layer 23. As shown in FIG. 2, the second lower passivation layer 29 may include third to sixth lower passivation layers 25, 26, 27, and 28 that are sequentially stacked. The passivation layers 25 to 29 may each have a single-layer or multi-layer structure of at least one of silicon oxide, silicon nitride, and silicon carbonitride.

Referring to FIG. 2, the bonding structure 30 may include a diffusion barrier BR1, a first upper conductive pad UP1 disposed on an upper surface of the first semiconductor chip 10, a diffusion barrier BR2, a second lower conductive pad LP2 disposed on a lower surface of the second semiconductor chip 20a, a protective metal layer PML interposed between the first upper conductive pad UP1 and the second lower conductive pad LP2, and intermetallic compounds IMC distributed in the protective metal layer PML. The first upper conductive pad UP1 and the second lower conductive pad LP2 may be formed of the same material. Although the diffusion barrier is described as a first diffusion barrier BR1 for the first upper conductive pad UP1 and a second diffusion barrier BR2 for the second lower conductive pad LP2, in examples where the diffusion barriers BR1 and BR2 are aligned or contact each other, the diffusion barriers BR1 and BR2 may be referred to as a single diffusion barrier BR.

The fourth upper passivation layer 18 of the first semiconductor chip 10 and the third lower passivation layer 25 of the second semiconductor chip 20a may directly contact each other, and the first upper conductive pad UP1 and the second lower conductive pad LP2 may contact each other with the protective metal layer PML therebetween, and thus the second semiconductor chip 20a may be bonded to the first semiconductor chip 10 through direct bonding or hybrid Cu bonding.

Referring to FIGS. 2 and 3, a first interface 10S may be between the first semiconductor chip 10 and the second semiconductor chip 20a. A second interface 31S may be between the second lower conductive pad LP2 and the protective metal layer PML. A third interface 33S may be between the first upper conductive pad UP1 and the protective metal layer PML. The second interface 31S and the third interface 33S may each have a concavo-convex structure. A first level LV1 of the first interface 10S may be equal to or lower than a second level LV2 of the second interface 31S.

The protective metal layer PML may include, for example, at least one of gold, silver, nickel, and tin. The intermetallic compound IMC may include, for example, copper and at least one of gold, silver, nickel, and tin. According to some embodiments of the disclosure, when the first upper conductive pad UP1 and the second lower conductive pad LP2 include copper and the protective metal layer PML includes silver, the intermetallic compound IMC may include silver and copper. In addition, copper atoms of the first upper conductive pad UP1 and the second lower conductive pad LP2 may diffuse through the second and third interfaces 31S and 33S to be distributed into the protective metal layer PML. The intermetallic compound IMC may increase strength of the protective metal layer PML and bonding strength between the first upper conductive pad UP1 and the second lower conductive pad LP2. As a result, the semiconductor package 1000 with improved durability may be provided. The diffusion barrier BR may surround the first upper conductive pad UP1, the second lower conductive pad LP2, and the protective metal layer PML. Multiple diffusion barriers BR may be provided and may directly contact each other. The diffusion barrier BR may include, for example, at least one of titanium, tantalum, titanium nitride, and tantalum nitride.

The first mold layer MD1 may cover an upper surface of the first semiconductor chip 10 and side surfaces of the second to fifth semiconductor chips 20a, 20b, 20c, and 20d. For example, the first mold layer MD1 may include an insulating resin such as epoxy-based molding compound (EMC). The first mold layer MD1 may further include a filler, and the filler may be dispersed in the insulating resin. The filler may include, for example, silicon oxide (SiO₂).

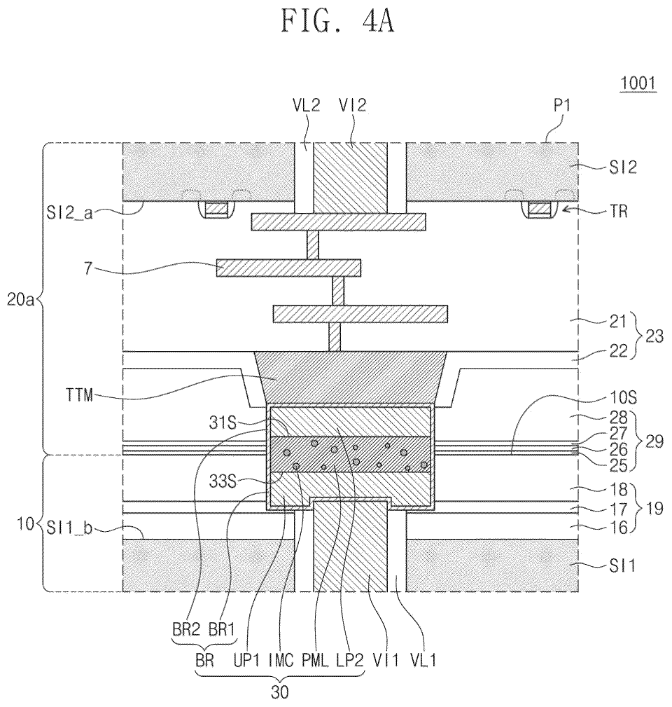

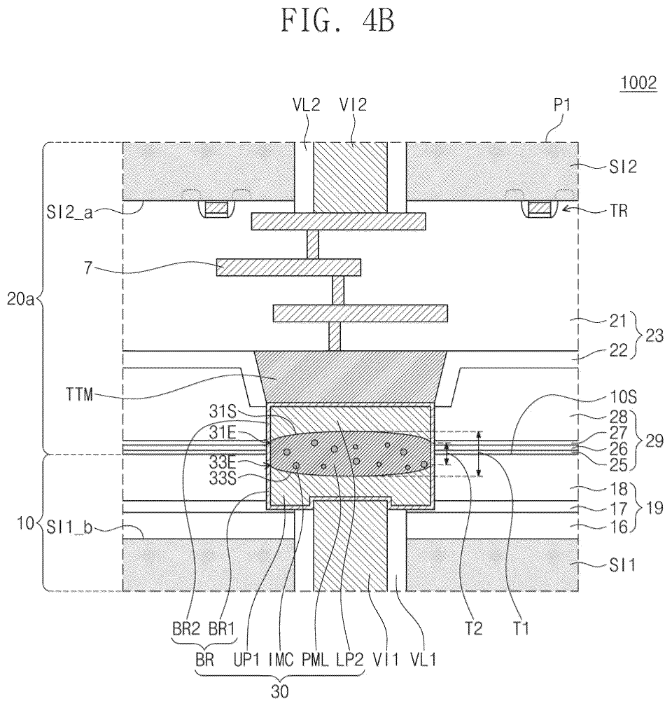

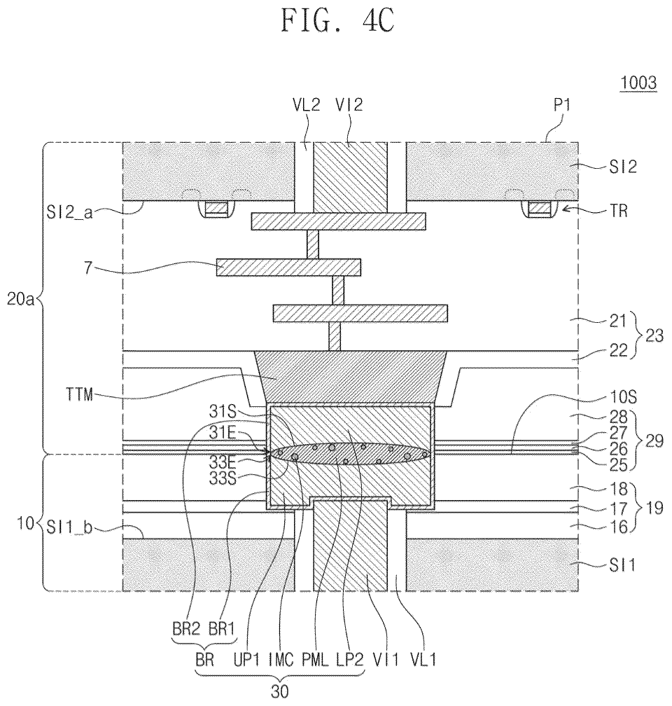

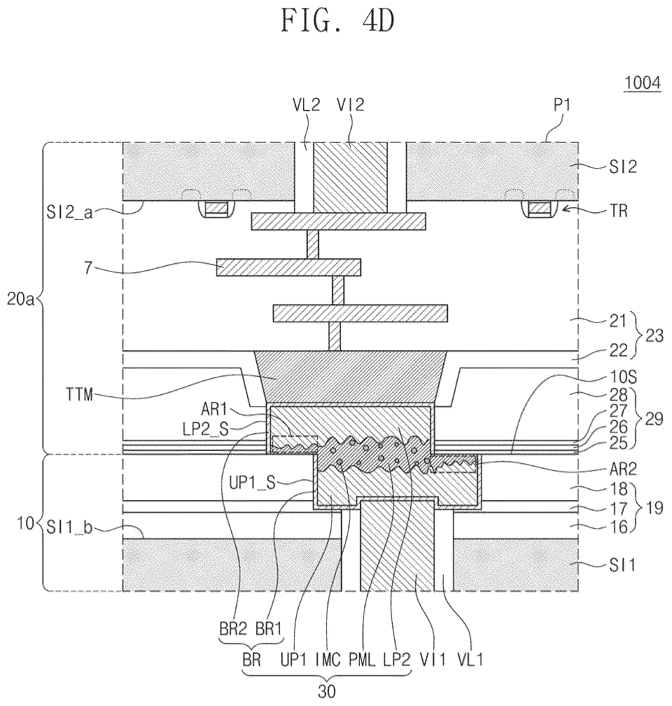

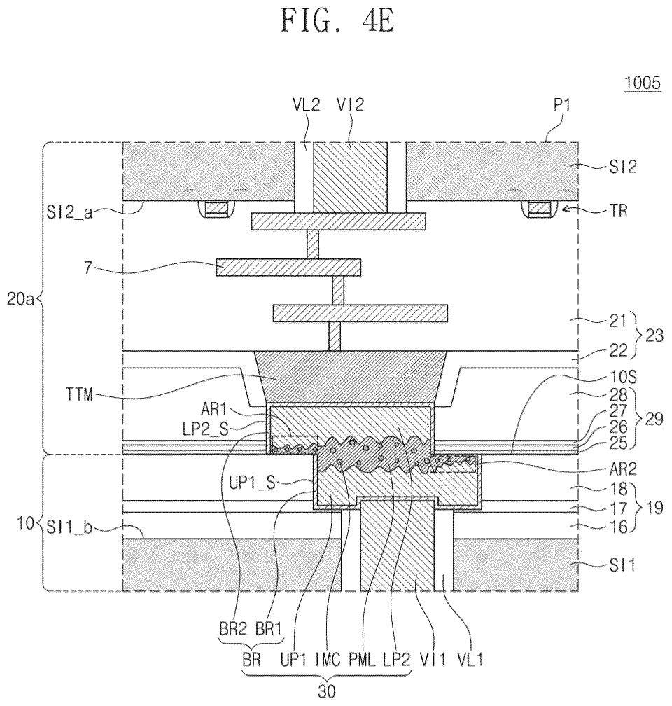

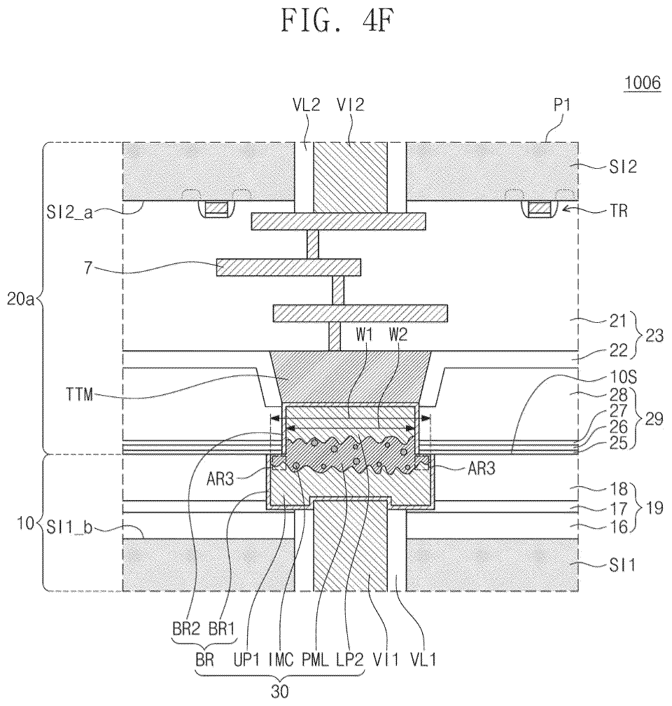

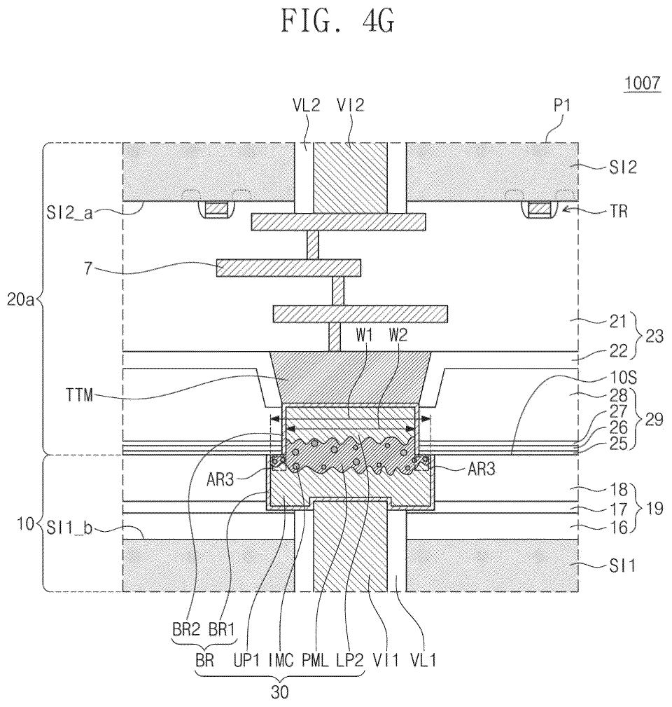

FIGS. 4A to 4G are enlarged views of additional examples corresponding to portion ‘P1’ of FIG. 1 according to one or more embodiments of the disclosure.

Referring to FIG. 4A, a semiconductor package 1001 according to some embodiments may have a structure in which the interfaces 31S and 33S between the conductive pads UP1 and LP2 and the protective metal layer PML in the structure of FIG. 2 have a flat structure. Other configurations may be the same/similar to those described with reference to FIGS. 1 to 3.

Referring to FIG. 4B, a semiconductor package 1002 according to some embodiments may have a structure in which the interfaces 31S and 33S between the conductive pads UP1 and LP2 and the protective metal layer PML in the structure of FIG. 2 are curved. A first edge portion 31E of the second interface 31S and a second edge portion 33E of the third interface 33S may be spaced apart from each other and may not contact each other. A first thickness T1 at a center of the protective metal layer PML may be greater than a second thickness T2 at an edge thereof. The first interface 10S may be positioned at a level equal to or lower than the first edge portion 31E of the second interface 31S. Other configurations may be the same/similar to those described with reference to FIGS. 1 to 3.

Referring to FIG. 4C, a semiconductor package 1003 according to some embodiments may have a structure in which the first edge portion 31E and the second edge portion 33E in the structure of FIG. 4B contact each other. In this case, the first interface 10S may be positioned at the same level as the first edge portion 31E and the second edge portion 33E. Other configurations may be the same/similar to those described with reference to FIGS. 1 to 3.

Referring to FIG. 4D, a semiconductor package 1004 according to some embodiments may have a structure in which the first upper conductive pad UP1 and the second lower conductive pad LP2 in the structure of FIG. 2 are bonded in an offset manner. A sidewall UP1_S of the first upper conductive pad UP1 and a sidewall LP2_S of the second lower conductive pad LP2 may be spaced apart and not contacting each other. The diffusion barrier BR1 of the first upper conductive pad UP1 and the diffusion barrier BR2 of the second lower conductive pad LP2 may be spaced apart from each other and may not contact each other. The second lower conductive pad LP2 may include a first region AR1 that does not contact the first upper conductive pad UP1. The first upper conductive pad UP1 may include a second region AR2 that does not contact the second lower conductive pad LP2. The protective metal layer PML present in the first and second regions AR1 and AR2 may not include the intermetallic compound IMC. Other configurations may be the same/similar to those described with reference to FIGS. 1 to 3.

Referring to FIG. 4E, a semiconductor package 1005 according to some embodiments may have a structure in which the protective metal layer PML in the first and second regions AR1 and AR2 in the structure of FIG. 4D includes the intermetallic compound IMC. Other configurations may be the same/similar to those described with reference to FIGS. 1 to 3 and 4D.

Referring to FIG. 4F, a semiconductor package 1006 according to some embodiments may have a structure in which a first width W1 of the first upper conductive pad UP1 is different from a second width W2 of the second lower conductive pad LP2 in the structure of FIG. 2. For example, the first width W1 may be larger than the second width W2. Alternatively, the first width W1 may be smaller than the second width W2. The diffusion barrier BR1 of the first upper conductive pad UP1 and the diffusion barrier BR2 of the second lower conductive pad LP2 may be spaced apart from each other and may not contact each other. The first upper conductive pad UP1 may include third regions AR3 that do not contact the second lower conductive pad LP2. The protective metal layer PML in the third regions AR3 may not include the intermetallic compound IMC. Other configurations may be the same/similar to those described with reference to FIGS. 1 to 3.

Referring to FIG. 4G, a semiconductor package 1007 according to some embodiments has a structure in which the protective metal layer PML in the third regions AR3 in the structure of FIG. 4F includes the intermetallic compound IMC. Other configurations may be the same/similar to those described with reference to FIGS. 1 to 3 and 4F.

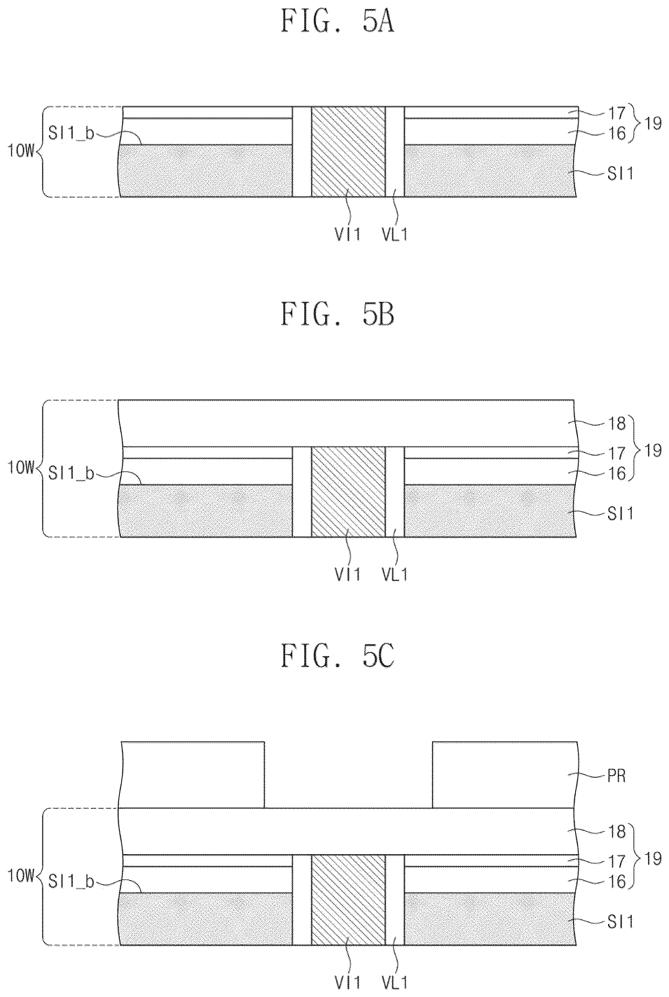

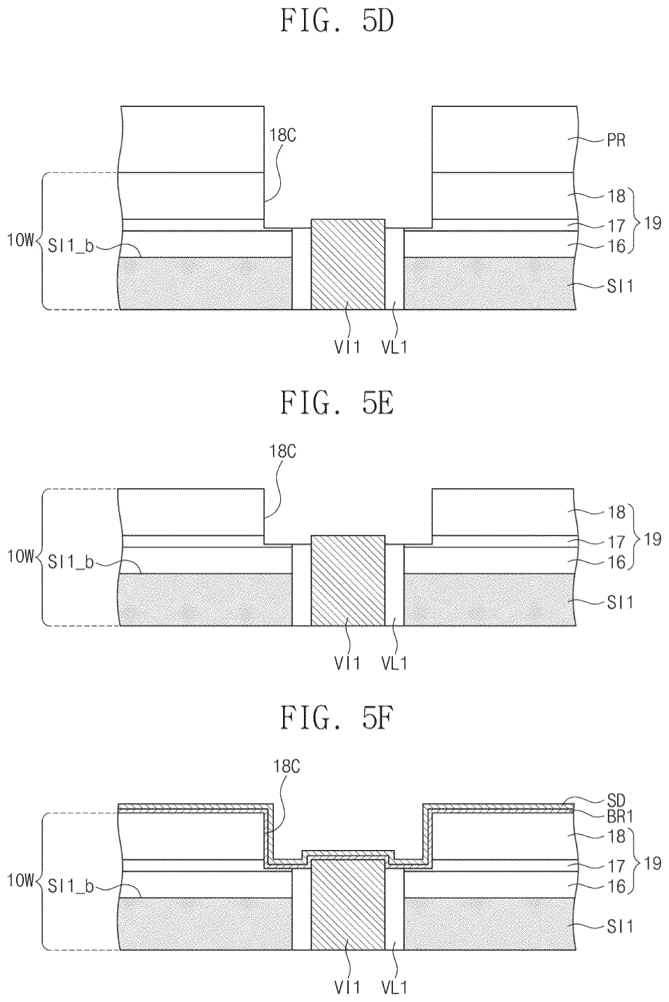

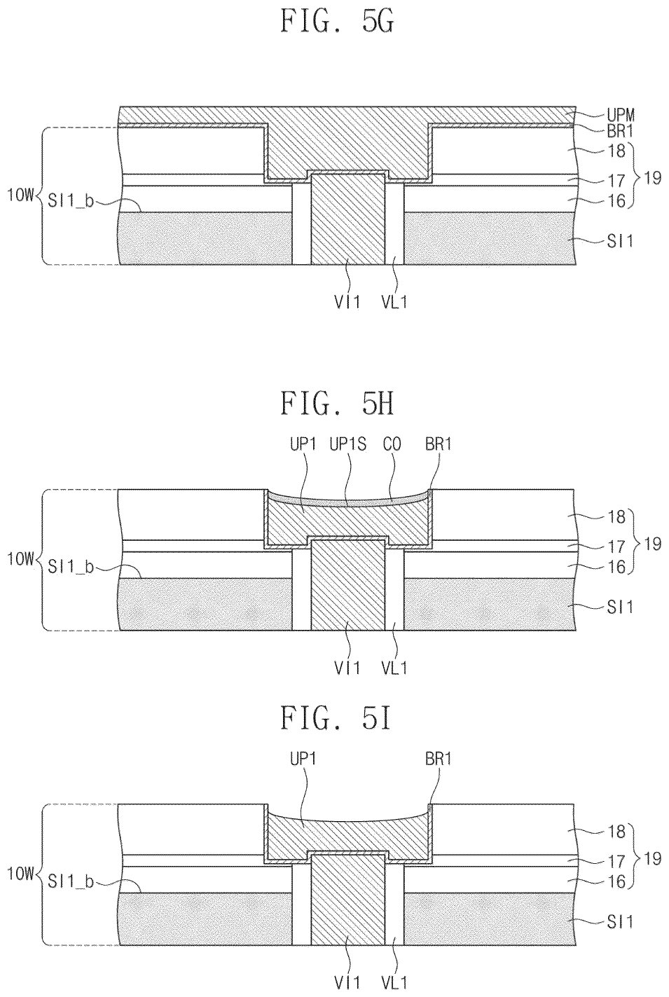

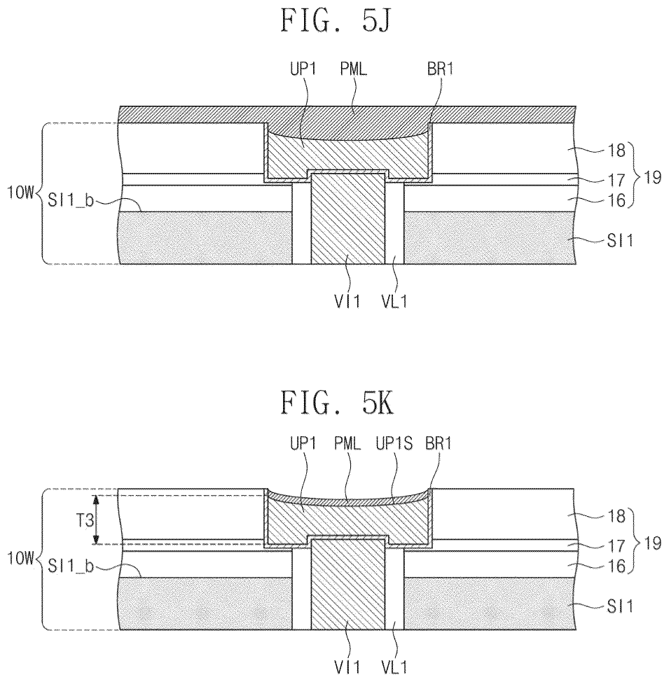

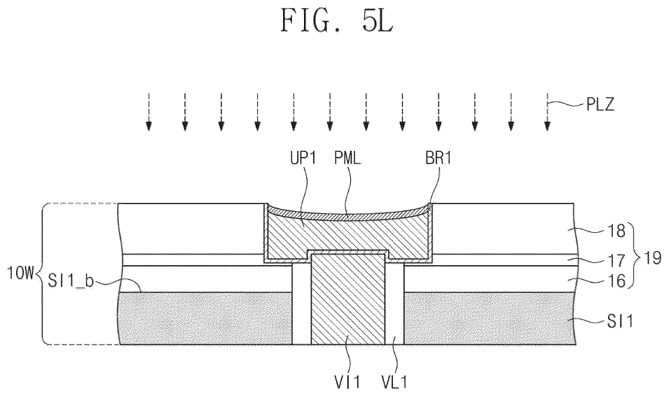

FIGS. 5A to 5L are cross-sectional views of a process for manufacturing the semiconductor package according to one or more embodiments of the disclosure. Hereinafter, description of aspects similar to that which is described above may be omitted.

Referring to FIG. 5A, a first semiconductor chip wafer 10W including a first through via VI1 and a first through insulating layer VL1 may be prepared. The first semiconductor chip wafer 10W may include a first substrate SI1. Second and third upper passivation layers 16 and 17 may be sequentially formed on a rear surface SI1_b of the first substrate SI1. The second and third upper passivation layers 16 and 17 may form the first upper passivation layer 19. The third upper passivation layer 17 may include SiN, for example. A chemical mechanical polishing (CMP) or etch-back process may be performed to remove at least a portion of the third upper passivation layer 17 and a portion of the first through insulating layer VL1 to expose an upper surface of the first through via VI1.

Referring to FIG. 5B, a fourth upper passivation layer 18 may be formed on the third upper passivation layer 17. The second to fourth upper passivation layers 16, 17, and 18 may form the first upper passivation layer 19. The fourth upper passivation layer 18 may include SiO₂, for example.

Referring to FIG. 5C, mask patterns PR for performing an etching process may be disposed on the fourth upper passivation layer 18.

Referring to FIG. 5D, an etching process may be performed to remove portion of the third and fourth upper passivation layers 17 and 18 and portion of the first through insulating layer VL1 to expose the first through via VI1. An opening 18C for forming the first upper conductive pad UP1 may be formed in a portion of the third and fourth upper passivation layers 17 and 18. The etching process may utilize, for example, wet etching or dry etching such as sputter etching or reactive ion etching.

Referring to FIG. 5E, the mask patterns PR may be removed and an upper surface of the fourth upper passivation layer 18 may be exposed.

Referring to FIG. 5F, a plating process may be performed to form a diffusion barrier BR to cover the opening 18C. The diffusion barrier BR may be formed to cover the upper surface of the fourth upper passivation layer 18. Afterwards, a first conductive layer SD may be formed to cover the diffusion barrier BR. The first conductive layer SD may include, for example, copper.

Referring to FIG. 5G, a plating process may be performed to form a second conductive layer UPM that fills the opening 18C. The second conductive layer UPM may include, for example, copper. The second conductive layer UPM may be fused with the first conductive layer SD to form an integrated body. The second conductive layer UPM may cover the diffusion barrier BR.

Referring to FIG. 5H, a CMP process may be performed, the diffusion barrier BR and the second conductive layer UPM on the fourth upper passivation layer 18 may be removed, and the second conductive layer UPM in the opening 18C may be partially removed to form a first upper conductive pad UP1. In this case, a first surface UP1S of the first upper conductive pad UP1 may be formed at a lower vertical level at a center thereof than at the edge thereof. However, the disclosure is not limited thereto. A surface of the diffusion barrier BR between the first upper conductive pad UP1 and the fourth upper passivation layer 18 may be exposed. After the CMP process for forming the first upper conductive pad UP1 is performed, the first upper conductive pad UP1 may be exposed to the air and copper oxide (CO) may be generated on the first surface UP1S. Copper oxide (CO) may increase electrical resistance between the conductive pads UP1 and LP2, thereby reducing operating speed of a semiconductor package 1000.

Referring to FIG. 5I, copper oxide (CO) on the first surface UP1S may be removed by performing an etching process. As a result, copper oxide (CO) may not be included between the first upper conductive pad UP1 and the protective metal layer PML (in FIG. 3) later. By removing copper oxide (CO), the electrical resistance between the conductive pads UP1 and LP2 may be reduced, thereby increasing the operating speed of the semiconductor package 1000. As a result, the semiconductor package 1000 with improved reliability may be provided.

Referring to FIG. 5J, a deposition process may be performed to form a protective metal layer PML covering the first upper conductive pad UP1, the diffusion barrier BR, and the fourth upper passivation layer 18. The deposition processes include physical vapor deposition (PVD), chemical vapor deposition (CVD), electroplating, spin-on deposition, and atomic layer deposition (ALD) may be used.

Referring to FIG. 5K, a CMP process may be performed, and the diffusion barrier BR, the protective metal layer PML on the fourth upper passivation layer 18, and a portion of the protective metal layer PML on the first upper conductive pad UP1 may be removed to form a protective metal layer PML on the first upper conductive pad UP1. The protection metal layer PML may prevent oxidation of the first upper conductive pad UP1 by completely covering the first surface UP1S of the first upper conductive pad UP1. As a result, the semiconductor package 1000 with improved reliability may be provided. The protective metal layer PML may not cover the diffusion barrier BR. A thickness of the protective metal layer PML may be 0.001 to 0.01 times a third thickness T3 of the first upper conductive pad UP1.

Referring to FIG. 5L, after forming the protective metal layer PML, a plasma treatment process PLZ may be performed on the fourth upper passivation layer 18 and the diffusion barrier BR to activate a surface of the fourth upper passivation layer 18. The protective metal layer PML completely may cover the first surface UP1S of the first upper conductive pad UP1, and thus copper ions of the first upper conductive pad UP1 may be prevented from diffusing into an edge of the first upper conductive pad UP1 and the diffusion barrier BR or onto the fourth upper passivation layer 18 when performing the plasma treatment process PLZ.

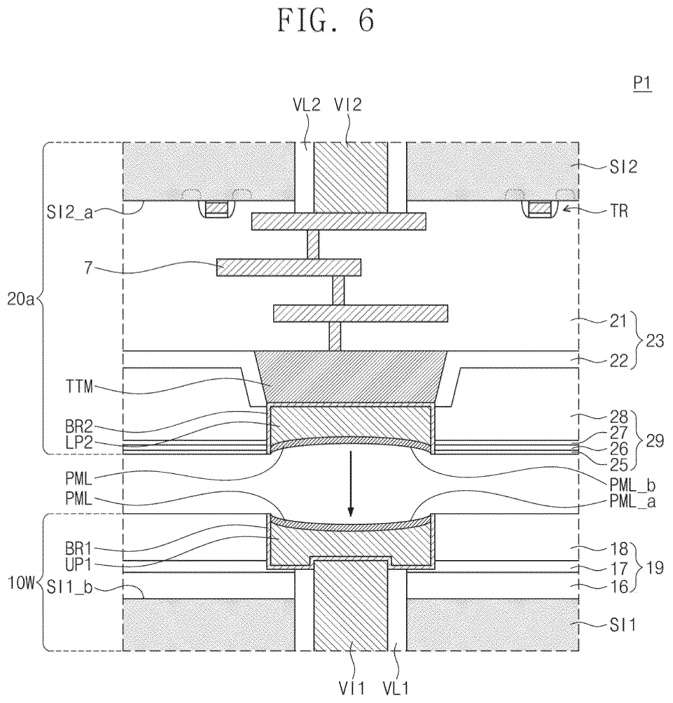

FIG. 6 is a diagram of a process of manufacturing the semiconductor package according to one or more embodiments of the disclosure.

Referring to FIG. 6, the second to fifth semiconductor chips 20a, 20b, 20c, and 20d of FIGS. 1 and 2 may be prepared. The structure of each of the second to fifth semiconductor chips 20a, 20b, 20c, and 20d may be the same as that described with reference to FIGS. 1 and 2. Although FIG. 6 only depicts the second semiconductor chip 20a, the description of FIG. 6 may also apply to the third semiconductor chip 20b, the fourth semiconductor chip 20c and/or the fifth semiconductor chip 20d.

The protective metal layer PML may be formed on the second lower conductive pad LP2 of the second semiconductor chip 20a. The protective metal layer PML may completely cover a surface of the second lower conductive pad LP2. Each of the second to fifth semiconductor chips 20a, 20b, 20c, and 20d may include the second upper conductive pads UP2, the second lower conductive pads LP2, and the protective metal layer PML. The second upper conductive pads UP2, second lower conductive pads LP2, and protective metal layer PML in each of the second to fifth semiconductor chips 20a, 20b, 20c, and 20d may be formed through similar processes as those in FIGS. 5F to 5L. A thickness of the protection metal layer PML in each of the second to fifth semiconductor chips 20a, 20b, 20c, and 20d may be 0.001 to 0.01 times a thickness of the second lower conductive pad LP2. The second to fifth semiconductor chips 20a, 20b, 20c, and 20d may be sequentially stacked on the first semiconductor chip wafer 10W. In this case, the second semiconductor chip 20a may be disposed on the first semiconductor chip wafer 10W such that the fourth upper passivation layer 18 and the third lower passivation layer 25 contact each other and the first upper conductive pad UP1 and the second lower conductive pad LP2 contact each other. Then, a heat compression process may be performed. As a result, the first semiconductor chip wafer 10W and the second to fifth semiconductor chips 20a, 20b, 20c, and 20d may be bonded to each other.

Through the thermal compression process, direct bonding (for example, hybrid Cu bonding) may be performed between the first upper conductive pad UP1 and the second lower conductive pad LP2, thereby forming the bonding structure 30 of FIG. 2. In this case, the diffusion barrier BR1 of the first upper conductive pad UP1 and the diffusion barrier BR2 of the second lower conductive pad LP2 may directly contact each other. As shown in FIG. 2, when the thermal compression process is performed, bonding surfaces PML_a and PML_b in the protective metal layer PML may be fused with each other to form an integrated body. In other words, there may be no interface in the protective metal layer PML. In addition, during the thermal compression process, copper atoms of the first upper conductive pad UP1 and the second lower conductive pad LP2 diffuse through the second and third interfaces 31S and 33S of FIG. 3 to form intermetallic compounds IMC in the protective metal layer PML. The intermetallic compound IMC may increase strength of the protective metal layer PML and bonding strength between the first upper conductive pad UP1 and the second lower conductive pad LP2.

When performing the plasma treatment process PLZ of FIG. 5L, the protective metal layer PML may prevent copper ions of the first upper conductive pad UP1 from diffusing into the edge of the first upper conductive pad UP1 and the diffusion barrier BR or onto the fourth upper passivation layer 18, thereby preventing and minimizing bonding defects between the upper passivation layer 18 and the lower passivation layer 25 in the thermal compression process.

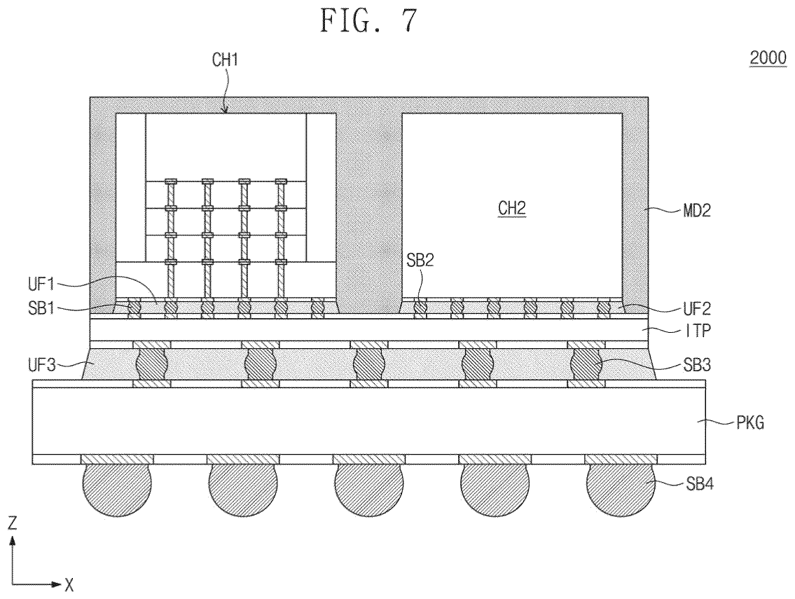

FIG. 7 is a cross-sectional view of a semiconductor package according to one or more embodiments of the disclosure.

Referring to FIG. 7, in a semiconductor package 2000 according to some embodiments, an interposer substrate ITP may be disposed on a package substrate PKG. The package substrate PKG may be, for example, a double-sided or multi-layer printed circuit board (PCB). The interposer substrate ITP may include silicon, for example. A first chip structure CH1 and a second chip structure CH2 may be arranged side by side in a first direction (e.g., the X direction) on the interposer substrate ITP. The interposer substrate ITP may include internal wirings connecting the first chip structure CH1 and the second chip structure CH2.

The first chip structure CH1 may be connected to the interposer substrate ITP through first external connection members SB1. The first chip structure CH1 may be the same/similar to the semiconductor package 1000 described with reference to FIGS. 1 to 5L. The first chip structure CH1 may include the bonding structure 30 described with reference to FIGS. 1 to 5L.

The second chip structure CH2 may be an application specific integrated circuit (order-specific semiconductor) chip or a system on chip. The second chip structure CH2 may also be referred to as a host, an application processor (AP), etc. Alternatively, the second chip structure CH2 may be a semiconductor chip that is the same/similar to the first chip structure CH1. The second chip structure CH2 may be connected to the interposer substrate ITP through second external connection members SB2.

A second mold layer MD2 may cover an upper surface of the interposer substrate ITP and the first and second chip structures CH1 and CH2. For example, the second mold layer MD2 may include an insulating resin such as epoxy-based molding compound (EMC). The second mold layer MD2 may further include a filler, and the filler may be dispersed in the insulating resin. The filler may include, for example, silicon oxide (SiO₂).

The interposer substrate ITP may be bonded to the package substrate PKG by third external connection members SB3. Fourth external connection members SB4 may be bonded to a bottom of the package substrate PKG. The external connection members SB1 to SB4 may include at least one of a copper bump, a copper pillar, and a solder ball. Underfills UF1 to UF3 filled between the first chip structure CH1 and the interposer substrate ITP, between the second chip structure CH2 and the interposer substrate ITP, and between the interposer substrate ITP and the package substrate PKG, respectively may be provided. The underfills UF1 to UF3 may be formed through dispensing and curing processes. The underfills UF1 to UF3 may include epoxy resin and protect the external connection members SB1 to SB3.

In the semiconductor package according to some embodiments, the protective metal layer may be interposed between the conductive pads disposed on the semiconductor chips. The protective metal layer may completely cover the surface of the conductive pads, thereby preventing the oxidation of the conductive pads and preventing the copper particles of the conductive pads from diffusing onto the protective layer or insulating layer around the conductive pads. Additionally, during the thermal compression process, the copper particles of the conductive pads may diffuse into the inside of the protective metal layer to form the intermetallic compound, thereby increasing the strength of the bonding region of the conductive pads. As a result, the bonding strength of conductive pads may be increased in the process of directly bonding semiconductor chips using the hybrid Cu bonding, and the semiconductor package with the improved durability and reliability may be provided.

Each of the embodiments provided in the above description is not excluded from being associated with one or more features of another example or another embodiment also provided herein or not provided herein but consistent with the disclosure.

While the disclosure has been particularly shown and described with reference to embodiments thereof, it will be understood that various changes in form and details may be made therein without departing from the spirit and scope of the following claims.

What is claimed is:

1. A semiconductor package comprising:
a first semiconductor chip;
a chip structure on the first semiconductor chip; and
a bonding structure between the first semiconductor chip and the chip structure,
wherein the bonding structure comprises:
a first conductive pad on an upper surface of the first semiconductor chip;
a second conductive pad on a lower surface of the chip structure;
a protective metal layer between the first conductive pad and the second conductive pad; and
an intermetallic compound in the protective metal layer,
wherein the protective metal layer covers a surface of the first conductive pad and a surface of the second conductive pad,
wherein the upper surface of the first semiconductor chip and the lower surface of the chip structure directly contact each other,
wherein the semiconductor package further comprises a first interface between the first semiconductor chip and the chip structure and a second interface between the protective metal layer and the second conductive pad, and
wherein a first level of the first interface is equal to or lower than a second level of the second interface.

2. The semiconductor package of claim 1, wherein the chip structure comprises a second semiconductor chip, a third semiconductor chip, a fourth semiconductor chip, and a fifth semiconductor chip that are sequentially stacked.

3. The semiconductor package of claim 2, wherein the first semiconductor chip further comprises a first through via,
wherein the second semiconductor chip, the third semiconductor chip, the fourth semiconductor chip, and the fifth semiconductor chip each comprise a second through via,
wherein the first through via is connected to the first conductive pad, and
wherein each of the second through vias are connected to the second conductive pad.

4. The semiconductor package of claim 1, wherein the first semiconductor chip further comprises a first upper passivation layer on the upper surface of the first semiconductor chip and a first lower passivation layer on a lower surface of the first semiconductor chip,
wherein the chip structure further comprises a second lower passivation layer on the lower surface of the chip structure, and
wherein the first upper passivation layer directly contacts the second lower passivation layer.

5. The semiconductor package of claim 1, wherein the bonding structure further comprises a diffusion barrier layer surrounding the first conductive pad and the second conductive pad.

6. The semiconductor package of claim 1, further comprising a third interface between the protective metal layer and the first conductive pad,
wherein the second interface and the third interface have a concavo-convex structure.

7. The semiconductor package of claim 1, wherein a thickness of a center of the protective metal layer is greater than a thickness of an edge of the protective metal layer.

8. The semiconductor package of claim 1, wherein the protective metal layer has a thickness of 0.001 to 0.01 times of a thickness of the first conductive pad and a thickness of the second conductive pad.

9. The semiconductor package of claim 1, wherein the protective metal layer comprises at least one of gold, silver, nickel, and tin, and
wherein the intermetallic compound comprises copper and at least one of gold, silver, nickel, and tin.

10. A semiconductor package comprising:
a first semiconductor chip comprising:
a first upper conductive pad on an upper surface of the first semiconductor chip;
a first lower conductive pad on a lower surface of the first semiconductor chip; and
a first through via connected to the first upper conductive pad and the first lower conductive pad;
a second semiconductor chip, a third semiconductor chip, a fourth semiconductor chip, and a fifth semiconductor chip sequentially stacked on the first semiconductor chip, wherein the second semiconductor chip comprises:
a second upper conductive pad on an upper surface of the second semiconductor chip; and
a second lower conductive pad on a lower surface of the second semiconductor chip; and
a first bonding structure between the first semiconductor chip and the second semiconductor chip, wherein the first bonding structure comprises:
the first upper conductive pad;
the second lower conductive pad;
a protective metal layer between the first upper conductive pad and the second lower conductive pad;
an intermetallic compound in the protective metal layer; and
a diffusion barrier surrounding the first upper conductive pad and the second lower conductive pad,
wherein the protective metal layer covers a surface of the first upper conductive pad and a surface of the second lower conductive pad,
wherein the upper surface of the first semiconductor chip and the lower surface of the second semiconductor chip directly contact each other,
wherein the semiconductor package further comprises a first interface between the first semiconductor chip and the second semiconductor chip and a second interface between the protective metal layer and the second lower conductive pad, and
wherein a first level of the first interface is equal to or lower than a second level of the second interface.

11. The semiconductor package of claim 10, wherein the first semiconductor chip further comprises a first upper passivation layer on the upper surface of the first semiconductor chip and a first lower passivation layer on the lower surface of the first semiconductor chip,
wherein the second semiconductor chip further comprises a second lower passivation layer on the lower surface of the second semiconductor chip, and
wherein the first upper passivation layer directly contacts the second lower passivation layer.

12. The semiconductor package of claim 10, further comprising a third interface between the protective metal layer and the first upper conductive pad,
wherein the second interface and the third interface have a concavo-convex structure.

13. The semiconductor package of claim 10, wherein a thickness of a center of the protective metal layer is greater than a thickness of an edge of the protective metal layer.

14. The semiconductor package of claim 10, wherein the protective metal layer has a thickness of 0.001 to 0.01 times of a thickness of the first upper conductive pad and the second lower conductive pad.

15. The semiconductor package of claim 10, wherein the protective metal layer comprises at least one of gold, silver, nickel, and tin, and
wherein the intermetallic compound comprises copper and at least one of gold, silver, nickel, and tin.

16. The semiconductor package of claim 10, further comprising:
a second bonding structure between the second semiconductor chip and the third semiconductor chip;
a third bonding structure between the third semiconductor chip and the fourth semiconductor chip; and
a fourth bonding structure between the fourth semiconductor chip and the fifth semiconductor chip.

17. The semiconductor package of claim 16, wherein each of the second bonding structure, the third bonding structure, and the fourth bonding structure comprises a respective protective metal layer and an intermetallic compound in the respective protective metal layer.

18. A semiconductor package comprising:
a package substrate;
an interposer substrate on the package substrate;
at least one semiconductor chip structure on the interposer substrate;
internal connection members connecting the interposer substrate and the at least one semiconductor chip structure; and
a mold layer at least partially covering the interposer substrate and the at least one semiconductor chip structure,
wherein the at least one semiconductor chip structure comprises:
a first semiconductor chip;
second semiconductor chips on the first semiconductor chip, the second semiconductor chips comprising a lowermost second semiconductor chip; and
a bonding structure between the first semiconductor chip and the lowermost second semiconductor chip,
wherein the bonding structure comprises:
a first conductive pad on an upper surface of the first semiconductor chip;
a second conductive pad on a lower surface of the lowermost second semiconductor chip;
a protective metal layer between the first conductive pad and the second conductive pad; and
an intermetallic compound in the protective metal layer,
wherein the protective metal layer covers a surface of the first conductive pad and a surface of the second conductive pad,
wherein the upper surface of the first semiconductor chip and the lower surface of the chip structure directly contact each other,
wherein the at least one semiconductor chip structure comprises a first interface between the first semiconductor chip and the second conductive pad and a second interface between the protective metal layer and the second conductive pad, and
wherein a first level of the first interface is equal to or lower than a second level of the second interface.

19. The semiconductor package of claim 18, wherein the at least one semiconductor chip structure comprises a third interface between the protective metal layer and the first conductive pad, and
wherein the second interface and the third interface have a concavo-convex structure.

20. The semiconductor package of claim 18, wherein the protective metal layer comprises at least one of gold, silver, nickel, and tin, and
wherein the intermetallic compound comprises copper and at least one of gold, silver, nickel, and tin.
